(19) United States
(12) Patent Application Publication
(10) Pub. No.: US 2025/0250668 A1
(43) Pub. Date: Aug. 7, 2025

(54) CONTINUOUS PROCESS FOR THE PREPARATION OF SILICON-CONTAINING COMPOSITE PARTICLES

(71) Applicant: NEXEON LIMITED, Abingdon (GB)

(72) Inventor: Jose MEDRANO CATALAN, Oxford Oxfordshire (GB)

(21) Appl. No.: 18/855,068

(22) PCT Filed: Apr. 11, 2023
(86) PCT No.: PCT/GB2023/050966

§ 371 Date: Oct. 8, 2024

(30) Foreign Application Priority Data
Apr. 8, 2022 (GB) 2205192.4
Apr. 22, 2022 (GB) 2205892.9

(51) Int. Cl. C23C 16/44; C01B 33/027; C23C 16/24; C23C 16/54; H01M 4/04; H01M 4/36; H01M 4/38; H01M 4/587

(52) U.S. Cl. CPC C23C 16/4417; C01B 33/027; C23C 16/24; C23C 16/54; H01M 4/0428; H01M 4/364; H01M 4/386; H01M 4/587; C01P 2006/40

(57) ABSTRACT

This invention relates to continuous process for preparing composite particles by continuous introduction of a porous particle feedstock and a silicon precursor gas into a first reaction zone and continuous withdrawal of a composite particles and an effluent gas from the first reaction zone, the composite particles comprising a porous particle framework and elemental silicon within the pores of the porous particle framework.

This invention relates in general to silicon-containing electroactive materials, and more specifically to continuous processes for the production of silicon-containing composite particles that are suitable for use as anode active materials in rechargeable lithium-ion batteries.

A typical lithium-ion battery (LIB) comprises an anode, a cathode and a lithium-containing electrolyte. The anode generally comprises a metal current collector provided with a layer of an electroactive material, defined herein as a material which is capable of inserting and releasing lithium ions during the charging and discharging of a battery. The terms “cathode” and “anode” are used herein in the sense that the battery is placed across a load, such that the anode is the negative electrode. When a LIB is charged, lithium ions are transported from the cathode via the electrolyte to the anode and are inserted into the electroactive material of the anode as intercalated lithium atoms. The term “battery” is used herein to refer both to devices containing a single lithium-ion cell and to devices containing multiple connected lithium-ion cells.

LIBs were developed in the 1980s and 1990s and have since found wide application in portable electronic devices. The development of electric or hybrid vehicles in recent has created a significant new market for LIBs and renewable energy sources have created further demand for on-grid energy storage which can be met at least in part by LIB farms. Overall, global production of LIBs is projected to grow from around 290 GWh in 2018 to over 2,000 GWh in 2028.

Alongside the growth in total storage capacity, there is significant interest in improving the gravimetric and/or volumetric capacities of rechargeable metal-ion batteries such that the same energy storage is achieved with less battery mass and/or less battery volume. Conventional LIBs use graphite as the anode electroactive material. Graphite anodes can accommodate a maximum of one lithium atom for every six carbon atoms resulting in a maximum theoretical specific capacity of 372 mAh/g in a lithium-ion battery, with a practical capacity that is somewhat lower (ca. 340 to 360 mAh/g).

Silicon is a promising alternative to graphite because of its very high capacity for lithium (see, for example, Insertion Electrode Materials for Rechargeable Lithium Batteries, Winter, M. et al. in Adv. Mater. 1998, 10, No. 10). Silican has a theoretical maximum specific capacity of about 3,600 mAh/g in a lithium-ion battery (based on Li₁₅Si₄). However, the intercalation of lithium into bulk silicon results in expansion of the silicon material by up to 400% of its original volume which can lead to failure of the battery. Repeated charge-discharge cycles cause significant mechanical stress, resulting in fracturing and delamination of the silicon. The formation of a solid electrolyte interphase (SEI) layer on the silicon surface consumes the electrolyte and newly exposed silicon surfaces on fracture surfaces results in further electrolyte decomposition and increased thickness of the SEI layer and irreversible consumption of lithium. These failure mechanisms collectively result in an unacceptable loss of electrochemical capacity over successive charging and discharging cycles.

The applicant has previously reported the development of a class of electroactive materials having a composite structure in which electroactive materials, such as silicon, are deposited into the pore network of a highly porous conductive particulate material, e.g. a porous carbon material (see WO 2020/095067 and WO 2020/128495). The silicon in these materials is finely divided with individual silicon structures having dimensions of the order of a few nanometres or less which therefore undergo minimal stress and strain during charging and discharging. As the silicon is confined to the pore volume of a porous material, exposure of the silicon surfaces to electrolyte is minimised, effectively limiting the extent of SEI formation. As a result, these materials exhibit good reversible capacity retention over multiple charge-discharge cycles.

The materials described in WO 2020/095067 and WO 2020/128495 has been synthesized by chemical vapour infiltration (CVI) in different reactor systems (static, rotary and FBR). The porous conductive particles are contacted with a flow of a silicon precursor gas, typically silane gas, at atmospheric pressure and at temperatures between 400 to 700° C. All these reactor configurations work as a batch mode for the solid carbon scaffold and as continuous mode for the silicon precursor gas. Reaction rates at these temperatures are fast, however, the silicon precursor gas molecules need to go through a tortuous path to access pore spaces of only a few nanometers in diameter. This means, that to obtain a homogeneous infiltration in such reactor systems, the reaction temperature needs to be relatively high to avoid mass transfer becoming a rate limiting step. Furthermore, the silicon precursor gas generally needs to be used at high dilution in an inert gas. Too high a concentration of the silicon precursor gas can result in rapid and uncontrolled deposition of silicon deposition in the outermost pores which then blocks access to much of the available pore volume. As a result, the deposited silicon does not have the fine structure associated with deposition in narrow pores, but is coarse and exposed and therefore demonstrates poor cycling behaviour. However, the use of low concentrations of the silicon precursor gas means that the reaction time to achieve the necessary silicon loading in the composite particles is relatively long, reducing throughput.

Another drawback of these systems is that a good mixing of the solids with the gas is required, otherwise the product batch may comprise compositional inhomogeneities. Solids having a higher contact time with the dilute silicon precursor gas will comprise a higher quantity of silicon than those with a shorter contact time with the unreacted silane gas flow; the deposition is not equal across the powder bed.

A further drawback of these systems is that batch operation is ill-suited to scale-up, and therefore producing large quantities of material is difficult.

There is therefore a need in the art for improved processes for preparing silicon-containing composite particles that are suitable for use as electroactive materials in LIBs. In particular, there is a need for processes for preparing such composite particles on a large-scale, with high throughput, while maintaining product quality.

### First Reaction Zone

In a first aspect, the invention provides a continuous process for preparing composite particles, the process comprising the steps of:
(a) providing a chemical vapour infiltration unit comprising at least a first reaction zone;
(b) providing a feedstock comprising porous particles and continuously introducing the porous particles into the first reaction zone;
(c) continuously introducing a silicon precursor gas into the first reaction zone;
(d) providing conditions in the reaction zone that are effective to cause deposition of silicon in the pores of the porous particles;
(e) continuously withdrawing composite particles comprising a porous particle framework and elemental silicon within the pores of the porous particle framework from the first reaction zone; and
(f) continuously withdrawing an effluent gas from the first reaction zone.

The invention therefore relates in general terms to a continuous process for preparing a composite particulate material in which nanoscale silicon domains are deposited into the pore network of porous particles by a process of chemical vapour infiltration, i.e. by the thermal decomposition of a silicon-containing precursor compound. The composite particles therefore comprise a first component in the form of porous particle framework that is derived from the porous particle feedstock identified in step (b), and a second component in the form of a plurality of nanoscale silicon domains that are disposed within the pore structure of the porous particle framework. As used herein, the term “nanoscale silicon domain” refers to a nanoscale body of elemental silicon having maximum dimensions that are determined by the location of the silicon within the micropores and/or mesopores of the porous particles.

The term continuous is used herein to distinguish the first reaction zone from batch-type operation. In a batch reactor, a batch of starting materials is added to a reactor in a first step, the reaction is allowed to progress for a specified period, and then a batch of product is withdrawn from the reactor. A batch reactor contains the full inventory of reacting materials for the duration of the reaction, and then the full inventory of products is removed. Continuous operation as defined herein refers to a reaction where the introduction of starting materials into the reaction zone and the withdrawal of products from the reaction zone both occur continuously and simultaneously with the reaction in progress, such that the reaction zone contains only a part of the inventory of the reacting materials.

A continuous reaction may be achieved by using a plug-flow type reactor wherein the reacting materials move along a pathway from a reactor inlet to a reactor outlet, such that the moving time defines the residence time of the particles in the reactor. Continuous operation may also be achieved in non-plug-flow using a reactor having an inlet and an outlet, but wherein there is no continuous pathway between the two—i.e. such that the particles are able to mix freely within the reaction zone. In non-plug-flow mode, the product withdrawn from the reaction zone will be a statistical mixture of material having a distribution of residence times. The rate at which starting materials are supplied to the reactor, the rate at which products are withdrawn, as well as the size of the reactor define the average residence time of material in the reactor. In principle, continuous operation does not exclude the possibility of deviations in the rate of flow of material to or from the reactor, for instance a continuous reactor may operate in a pulsed mode. However, as defined herein, continuous operation of a reactor meets the condition that the introduction of starting materials into the reaction zone and the withdrawal of products from the reaction zone both occur continuously and simultaneously with the reaction in progress, such that the reaction zone contains only a part of the inventory of the reacting materials.

The first reaction zone preferably operates in plug-flow mode in respect of the particles, such that the reactor has an axial direction and mixing of particles in the axial direction is limited such that the particle residence time in the reactor has a narrow distribution. Plug-flow mode is defined herein as a residence time distribution wherein the standard deviation of the residence time is no more than 30%, more preferably no more than 20%, more preferably no more than 10% of the mean residence time, more preferably no more than 5% of the mean residence time. Since the residence time of all of the particles in plug-flow mode is essentially the same (assuming limited axial mixing), this mode of operation results in a composite particle product that is more homogeneous in its composition than where the reaction is carried out in non-plug flow mode.

For operation in plug-flow mode, the reaction zone of the chemical vapour infiltration (CVI) unit preferably has the form of a continuous tubular reactor having a first end, a second end and a length, wherein the porous particles are introduced via a particle inlet at the first end of the tubular reactor and wherein the composite particles are withdrawn via a particle outlet at the second end of the tubular reactor. The cross-section of the tubular reactor may be any suitable shape. For example, the cross-section of the tubular reactor may be circular, elliptical, rectangular or square or irregular in shape.

The tubular reaction zone may be arranged substantially horizontally across its length, for example with a slope of less than ±20° from the horizontal, preferably less than ±10°. The porous particles increase in density as silicon is deposited in the pores and a horizontal arrangement of the tubular reaction zone prevents backmixing of particles as they move from the particle inlet to the particle outlet. Alternatively, the tubular reaction zone may be arranged with a negative gradient, such that the particle outlet is disposed below the particle inlet. Alternatively, the tubular reaction zone may be arranged vertically, such that the particle inlet is at the top of the tubular reaction zone and the particle outlet is at the bottom of the tubular reaction zone.

The tubular reactor may be operated as a co-current or counter-current reactor. In co-current operation, the silicon precursor gas is introduced via an inlet proximal to the first end of the tubular reactor and the effluent gas is withdrawn via a gas discharge outlet proximal to the second end of the tubular reactor. In counter-current operation, the silicon precursor gas is introduced via an inlet proximal to the second end of the tubular reactor and the effluent gas is withdrawn via a gas discharge outlet proximal to the first end of the tubular reactor.

More preferably, the silicon precursor gas may be introduced into the tubular reactor via a plurality of inlets spaced apart along the length of the tubular reactor. In this case, the effluent gas may be withdrawn via one or more gas discharge outlets disposed at any position along the length of the tubular reactor. For example, where the silicon precursor gas is introduced via a plurality of inlets spaced apart along the length of the tubular reactor, the effluent gas may be withdrawn: (i) via a gas discharge outlet proximal to the second end of the tubular reactor; or (ii) via a gas discharge outlet proximal to the first end of the tubular reactor; or (iii) via a plurality of gas discharge outlets spaced apart along the length of the tubular reactor.

The use of a plurality of inlets spaced apart along the length of the tubular reactor for the silicon precursor gas may be advantageous to ensure that the concentration of the silicon precursor gas is substantially uniform along the length of the reaction zone. In the case that the reactor is operated in a simple co-current or counter-current mode, the concentration of the silicon precursor gas in the reactor declines from the inlet to the effluent gas outlet. As a result, the rate of reaction within the portion of the reaction zone adjacent the silicon precursor gas inlet will be elevated and the reaction rate is reduced for the remainder of the length of the reaction zone. Depending on the reactor conditions, the excess rate of reaction adjacent the silicon precursor gas inlet can lead to the type of uncontrolled deposition described above, where a high deposition rate results in rapid blocking of the pore spaces such that the silicon precursor gas can no longer infiltrate the fine pore structure and silicon is deposited instead as coarse domains that demonstrate unacceptably poor cycling behaviour in LIBs.

The tubular reactor preferably comprises a means for conveying particles from the first end to the second end thereof. The means for conveying particles from the first end to the second end of the tubular reactor may comprise at least one auger, defined herein as a rotating shaft disposed axially within the reactor and having a helical form, such that rotation of the shaft conveys the porous particles along the length of the tubular reactor. Optionally, the apparatus for conveying particles from the first end to the second end of the tubular reactor comprises a pair of cooperating augers, wherein the helices of each auger are arranged to overlap. As a result, of this twin auger arrangement, particles are exchanged from the path of one auger to the path of each other which facilitates radial mixing and heat transfer within the particles as they are conveyed through the tubular reaction zone.

Optionally, the tubular reactor preferably comprises both an apparatus for conveying particles from the first end to the second end thereof and internal mixing elements, e.g. paddles for radial mixing of the particles. For instance, the apparatus for conveying particles may comprise an auger as described above wherein the auger is provided with additional mixing elements and/or blade modifications that effect radial mixing. Alternatively, the reactor wall may comprise geometrical features that effect radial mixing.

Optionally, the tubular reactor rotates and comprises both geometrical features for conveying particles from the first end to the second end thereof, e.g. helical flights, and internal mixing geometrical elements, e.g. paddles for radial mixing of the particles. For instance, the apparatus for conveying particles may comprise a helical flight with additional mixing elements and/or blade modifications that effect radial mixing.

Optionally, the tubular reactor comprises moving internals that convey the powder from the first end to the second end thereof, where the moving internals optionally comprise a moving belt type conveyor, a bucket type conveyor, or a tube chain type conveyor, or a vertical conveyor. For instance, the apparatus for conveying particles may comprise a vertical bucket conveyor or several vertical bucket conveyors, or a vertical conveyor belt in a heated reactor vessel providing a means of continuous introduction of porous particles and continuous withdrawal of composite particles.

Optionally, the tubular reactor preferably consists of a vertical vibrated screw conveyor furnace.

As an alternative means for conveying particles from the first end to the second end thereof, the tubular reactor may comprise a vibrating surface. In this embodiment, the porous particles are conveyed by vibration through the tubular reactor from the first end to the second end thereof. Preferably, the amplitude of vibration is between 0.01 mm and 10 cm, more preferably between 0.1 mm to 10 cm, more preferably from 1 cm to 10 cm. The frequency of vibration is suitably from 0.01 to 100 Hz, more preferably from 0.1 to 10 Hz.

The temperature in the first reaction zone is preferably in the range from 340 to 500° C., more preferably from 350 to 480° C., more preferably from 350 to 450° C., more preferably from 350 to 420° C., more preferably from 350 to less than 400° C., more preferably from 355 to 395° C., more preferably from 360 to 390° C., more preferably from 365 to 385° C., more preferably from 370 to 385° C., for example from 370 to 395° C. Alternatively, the temperature in the first reaction zone may be in the range from 400 to 500° C., or 400 to 490° C., or 400 to 480° C., or 400 to 470° C., or 400 to 460° C.

The process of the invention is preferably operated under a regime where the silicon precursor gas is supplied to the first reaction zone at high concentration, or even in neat form. In order to control the rate of reaction and to achieve controlled infiltration of the silicon precursor gas into the pore network of the porous particles, the reaction temperature in the first reaction zone is no more than 420° C., more preferably no more than 410° C., more preferably no more than 400° C., more preferably no more than 395° C.

The pressure in the first reaction zone is preferably in the range from 1 to 10000 kPa, or from 10 to 6000 kPa, or from 20 to 4000 kPa, or from 50 to 2000 kPa, or from 80 to 1500 kPa, or from 90 to 1000 kPa, or from 90 to 600 kPa or about 100 kPa.

Optionally, the first reaction zone may be operated above atmospheric pressure, for example at a pressure from 110 to 10000 kPa, or from 120 to 5000 kPa, or from 150 to 2000 kPa, or from 200 to 1800 kPa, or from 200 to 1600 kPa, or from 250 to 1500 kPa, or from 300 to 1200 kPa, or from 400 to 1000 kPa, or from 500 to 900 kPa, or from 600 to 800 kPa.

The pressure in the first reaction zone may be no more than 650 kPa, or no more than 600 kPa, or no more than 500 kPa. For example, the pressure may be in the range from 100 to 600 kPa. The pressure in the first reaction zone may be from 1 to 600 kPa, or from 10 to 500 kPa, or from 20 to 200 kPa, or from 50 to 150 kPa, or from 80 to 120 kPa, or about 100 kPa. Operation at elevated pressure has the advantage that mass transfer limitations on the reaction rate are reduced, facilitating infiltration of the silicon precursor gas into the pore network of the porous particles. However, to prevent uncontrolled reaction, the temperature in the reaction zone is preferably reduced as the pressure is increased. In particular, where the pressure in the first reaction zone is above 100 kPa, the reaction temperature in the first reaction zone is preferably no more than 450° C., more preferably no more than 430° C., more preferably no more than 420° C., more preferably no more than 410° C., more preferably no more than 400° C., more preferably no more than 395° C. All pressure values disclosed herein are absolute pressures unless specified otherwise.

The mean residence time of particles in the first reaction zone between introduction of porous particles into the first reaction zone in step (b) and withdrawal of composite particles from the first reaction zone in step (e) is preferably from 10 to 300 minutes, or from 15 to 240 minutes, or from 20 to 180 minutes, or from 30 to 120 minutes, or from 40 to 90 minutes. The mean residence time can typically be calibrated for any given reactor based on the reactor dimensions and the speed of operation of any mechanical apparatus for conveying particles through the reaction zone.

As noted above, the first reaction zone preferably operates essentially in plug-flow mode in respect of the particles. Deviations in the residence time of the particles, resulting in broadening of the particle residence time distribution, can be prevented by the use of reaction vessels having internals that prevent axial mixing. For example, in a tubular reactor as described above, comprising at least one auger to convey particles through the reaction zone, the pitch of the auger screw can determine the degree of axial mixing. Preferably, the pitch of auger blades used in a tubular reactor according to the invention is no more than 1.5 times the outer diameter of the auger blades, more preferably no more than 1.2 times the outer diameter of the auger blades, more preferably no more than 1.0 times the outer diameter of the auger blades. Preferably, the first reaction zone has a length that is at least 5 times the pitch of the auger blades, more preferably at least 8 times the pitch of the auger blades, more preferably at least 10 times the pitch of the auger blades.

The volume of the first reaction zone in litres (L) is preferably in the range from (0.003 L·g⁻¹× F_{PP}×RT) to (0.06 L·g⁻¹×Fₚₚ×RT), wherein F_{PP} is the feed rate of porous particles to the first reaction zone in grams per minute, and wherein RT is the mean residence time of particles in the first reaction zone in minutes. In other words, the first reaction zone has a reactor volume of 3 cm³ to 60 cm³ per gram of porous particles introduced into the reactor per residence time interval. For example, a charge of 100 g/h of porous particles and a mean residence time of 1 h, would necessitate a reactor volume from 0.3 L to 6 L. Preferably, the volume of the first reaction zone in litres (L) is less than (0.05 L·g⁻¹×F_{PP}×RT), more preferably less than (0.04 L·g⁻¹×F_{PP}×RT), more preferably less than (0.03 L·g⁻¹×Fₚₚ×RT), more preferably less than (0.02 L·g⁻¹×F_{PP}×RT), more preferably less than (0.01 L·g⁻¹×F_{PP}×RT), more preferably less than (0.009 L·g⁻¹×F_{PP}×RT, more preferably less than (0.008 L·g⁻¹×F_{PP}×RT, more preferably less than (0.007 L·g⁻¹×F_{PP}×RT, more preferably less than (0.006 L·g⁻¹×F_{PP}×RT. A low reactor volume relative to the mass of particles charged to the reactor is advantageous in that it may reduce axial mixing of particles, such that the reactor closely approximates an idealised plug flow reactor.

The ratio of the feed rate of the silicon precursor gas to the first reaction zone to the feed rate of the porous particles to the first reaction zone is preferably from 0.25 to 2, or from 0.4 to 1.9, or from 0.6 to 1.8, or from 0.7 to 1.7, or from 0.8 to 1.6, or from 0.9 to 1.6, or from 1 to 1.5, based on grams of silicon in the silicon precursor gas per gram of porous particles. In other words, during the residence time of the particles in the first reaction zone, from 0.25 to 2 grams of silicon (in the form of the silicon precursor gas) is introduced into the reactor per gram of porous particles.

Preferably, the first reaction zone is operated such that consumption of the silicon precursor gas is at least 20%, preferably at least 50%, preferably at least 60%, preferably at least 80%, preferably at least 90%. Optionally, the first reaction zone is operated such that consumption of the silicon precursor gas is no more than 99%, or no more than 98%. A low level of unreacted silicon precursor gas in the effluent gas may be used as an indicator of controlled reaction rate.

Preferably, the composite particles withdrawn from the first reaction zone comprise from 0.2 to 1.8 grams of silicon per gram of the porous particle framework.

The ratio of the feed rate of the silicon precursor gas to the first reaction zone to the feed rate of the porous particles is based on fresh feed of the silicon precursor gas. It is not excluded that unreacted silicon precursor gas may be recovered from the effluent gas withdrawn from the first reaction zone in step (f) and recycled into the first reaction zone. Silicon precursor gas recycled to the first reaction zone in this way is not included in the feed ratio described above.

The effluent gas from the first reaction zone comprises by product gases from the CVI reaction and optionally unreacted silicon precursor gas. In the case that the effluent gas from the first reaction zone contains significant quantities of unreacted silicon precursor gas, it may be appropriate to recover the unreacted silicon precursor gas from the effluent gas and to recycle the recovered silicon precursor gas to the first reaction zone. Means of recovering the unreacted silicon precursor gas from the effluent gas include semi-permeable membrane separation processes, pressure-swing absorption processes, and cryogenic separation processes.

Optionally, silicon precursor gas is pre-heated before it is introduced into the first reaction zone. Preferably, the silicon precursor gas is pre-heated to a temperature that is ≥(T_{RZ}−200)° C., wherein T_{RZ} is the reaction temperature of the first reaction zone, preferably to a temperature that is ≥(T_{RZ}−100)° C., more preferably to a temperature that is ≥(T_{RZ}−50)° C.

The process as defined in steps (a) to (f) is preferably operated under steady state conditions so as to ensure uniformity over time of the composite particles that are withdrawn from the first reaction zone in step (e).

The process of the invention optionally further comprises monitoring the partial pressure of the silicon precursor gas in the effluent gas withdrawn from the first reaction zone, and optionally adjusting one or more of the temperature in the first reaction zone, the pressure in the first reaction zone, or the feed rate of the silicon precursor gas to the first reaction zone in response to a measured deviation in the partial pressure of the silicon precursor gas from a steady state partial pressure.

### Pre-Heating Zone

Step (b) preferably comprises pre-treatment of the porous particles prior to their introduction into the first reaction zone. In particular, step (b) preferably further comprises pre-heating the feedstock comprising the porous particles in a pre-heating zone before introducing the pre-heated feedstock into the first reaction zone. Preferably, the feedstock comprising the porous particles is pre-heated to a temperature that is ≥(T_{RZ}−50)° C., wherein T_{RZ} is the reaction temperature of the first reaction zone, preferably a temperature that is ≥(T_{RZ}−30)° C., preferably a temperature that is ≥(T_{RZ}−20)° C.

The preheating zone may optionally take the form of a tubular vessel having a first end, a second end and a length, wherein the porous particles are introduced via a particle inlet at the first end of the tubular vessel and wherein the composite particles are withdrawn via a particle outlet at the second end of the vessel reactor. One or more heating elements is arranged along the length of the tubular vessel and the tubular vessel preferably comprises conveying means to transport the porous particles from the particle inlet to the particle outlet.

Preferably, the preheating zone is flushed with an inert gas during preheating of the porous particles, for instance an inert gas selected from nitrogen and argon. Optionally, the preheating zone may be operated under vacuum. For example, the pressure of the preheating zone may be less than 100 kPa, or less than 80 kPa, or less than 60 kPa, or less than 40 kPa, or less than 20 kPa.

### Second Reaction Zone

The CVI unit optionally comprises at least first and second reaction zones, such that the CVI reaction is carried out in at least two stages. Where the CVI unit comprises first and second reaction zones, the first reaction zone may be as defined above, and the process further comprises
(g) continuously introducing into the second reaction zone the composite particles withdrawn from the first reaction zone in step (e);
(h) continuously introducing a silicon precursor gas into the second reaction zone;
(i) providing conditions in the second reaction zone that are effective to cause deposition of silicon in the pores of the porous particles;
(j) continuously withdrawing composite particles comprising a porous particle framework and elemental silicon within the pores of the porous particle framework from the second reaction zone; and
(k) continuously withdrawing an effluent gas from the second reaction zone.

One of the advantages of a staged CVI process using more than one reaction zone is that different CVI reaction conditions may be applied in each of the reaction zones. For instance, the majority of the silicon deposition may take place in the first reaction zone and the second reaction zone may be operated under conditions that ensure fine control of the later stage of deposition, by which time the available pore volume is depleted and uncontrolled deposition would result in undesirable deposition of coarse domains of silicon, in particular on the outer surfaces of the porous particles.

The second reaction zone preferably operates in plug-flow mode in respect of the particles, as described above.

The second reaction zone may optionally comprise a tubular reactor having any of the features of the tubular reactor described in connection with the first reaction zone. In particular, the first and second reaction zones may comprise respective tubular reactors with a means for conveying composite particles withdrawn from the first reaction zone in step (e) to the second reaction zone in step (g).

The tubular reactor of the second reaction zone may be operated as a co-current or counter-current reactor. More preferably, the silicon precursor gas may be introduced into the tubular reactor of the second reaction zone via a plurality of inlets spaced apart along the length of the tubular reactor. In this case, the effluent gas from the second reaction zone may be withdrawn via one or more gas discharge outlets disposed at any position along the length of the tubular reactor as described for the first reaction zone.

The tubular reactor of the second reaction zone preferably comprises an apparatus for conveying particles from the first end to the second end thereof, such as at least one auger, optionally a pair of cooperating augers, wherein the helices of each auger are arranged to overlap.

Optionally, the tubular reactor preferably rotates and comprises geometrical features for conveying particles from the first end to the second end thereof, e.g. helical flights, and internal mixing geometrical elements, e.g. paddles for radial mixing of the particles. For instance, the apparatus for conveying particles may comprise a helical flight with additional mixing elements and/or blade modifications that effect radial mixing.

Optionally, the tubular reactor comprises moving internals that convey the powder from the first end to the second end thereof, where the moving internals optionally comprise a moving belt type conveyor, a bucket type conveyor, or a tube chain type conveyor, or a vertical conveyor. For instance, the apparatus for conveying particles may comprise a vertical bucket conveyor or several vertical bucket conveyors, or a vertical conveyor belt in a heated reactor vessel providing a means of continuous introduction of porous particles and continuous withdrawal of composite particles.

Optionally, the reactor preferably consists of a vertical vibrated screw conveyor furnace.

As an alternative means for conveying particles from the first end to the second end thereof, the tubular reactor may comprise a vibrating surface. In this embodiment, the porous particles are conveyed by vibration through the tubular reactor from the first end to the second end thereof. Preferably, the amplitude of vibration is between 0.01 mm and 10 cm, more preferably between 0.1 mm to 10 cm, more preferably from 1 cm to 10 cm. The frequency of vibration is suitably from 0.01 to 100 Hz, more preferably from 0.1 to 10 Hz.

The temperature in the second reaction zone is preferably in the range from 350 to 450° C., or from 350 to 420° C., or from 350 to less than 400° C., or from 355 to 395° C., or from 360 to 390° C., or from 365 to 385° C. or from 370 to 385° C., for example from 370 to 395° C.

The pressure in the second reaction zone is preferably in the range from 1 to 10000 kPa, or from 10 to 6000 kPa, or from 20 to 4000 kPa, or from 50 to 2000 kPa, or from 80 to 1500 kPa, or from 90 to 1000 kPa, or from 90 to 600 kPa or about 100 kPa.

Optionally, the second reaction zone may be operated above atmospheric pressure, for example at a pressure from 110 to 10000 kPa, or from 120 to 5000 kPa, or from 150 to 2000 kPa, or from 200 to 1800 kPa, or from 200 to 1600 kPa, or from 250 to 1500 kPa, or from 300 to 1200 kPa, or from 400 to 1000 kPa, or from 500 to 900 kPa, or from 600 to 800 kPa.

The pressure in the second reaction zone may be no more than 650 kPa, or no more than 600 kPa, or no more than 500 kPa. For example, the pressure may be in the range from 100 to 600 kPa. The pressure in the second reaction zone may be from 1 to 600 kPa, or from 10 to 500 kPa, or from 20 to 200 kPa, or from 50 to 150 kPa, or from 80 to 120 kPa, or about 100 kPa. Where the pressure in the second reaction zone is above 100 kPa, the reaction temperature in the second reaction zone is preferably no more than 450° C., more preferably no more than 430° C., more preferably no more than 420° C., more preferably no more than 410° C., more preferably no more than 400° C., more preferably no more than 395° C.

In order to control the rate of reaction and to achieve controlled infiltration of the silicon precursor gas into the pore network of the porous particles, the reaction temperature in the second reaction zone is no more than 420° C., more preferably no more than 410° C., more preferably no more than 400° C., more preferably no more than 395° C.

Preferably, the operation of the first and second reaction zones differs in respect of one or more of the reaction temperature, the reaction pressure, the particle residence time, and the feed rate of the silicon precursor gas. In particular, it is preferred that the second reaction zone is operated under conditions such that the rate of deposition of silicon is reduced in the second reaction zone as compared to the first reaction zone and/or such that the total mass of silicon deposited in the second reaction zone is less than is deposited in the first reaction zone.

For example, the reaction temperature in the second reaction zone is optionally from 5 to 50° C. lower, or from 10 to 20° C. lower than the reaction temperature in the first reaction zone.

The mean residence time of particles in the second reaction zone between introduction of composite particles into the second reaction zone in step (g) and withdrawal of composite particles from the second reaction zone in step (j) is preferably from 2 to 60 minutes, or from 5 to 30 minutes, or from 10 to 20 minutes. Preferably, the mean residence time of particles in the second reaction zone is less than the mean residence time of particles in the first reaction zone.

The second reaction zone preferably operates in plug-flow mode, as described above.

The volume of the second reaction zone in litres (L) is preferably in the range from (0.001 L·g⁻¹×F_{CP}×RT) to (0.02 L·g⁻¹×F_{CP}×RT), wherein F_{CP} is the feed rate of composite particles to the second reaction zone based on grams of the porous particle framework per minute, and wherein RT is the mean residence time of particles in the second reaction zone in minutes. Preferably, the volume of the second reaction zone in litres (L) is less than (0.01 L·g⁻¹×F_{CP}×RT), more preferably less than (0.008 L·g⁻¹×F_{CP}×RT), more preferably less than (0.007 L·g⁻¹×F_{CP}×RT), more preferably less than (0.006 L·g⁻¹×F_{CP}×RT), more preferably less than (0.005 L·g⁻¹×F_{CP}×RT), more preferably less than (0.004 L·g⁻¹×F_{CP}×RT).

For ease of comparison between the first and second reaction zones, the mass of composite particles in the second reaction zone, and reaction parameters defined by reference to the mass of composite particles in the second reaction zone, are normalized to the mass of the porous particle framework. Accordingly, the mass of silicon added to the composite particles per gram of the porous particle feedstock in each of the first and second reaction zones can be directly compared.

The ratio of the feed rate of the silicon precursor gas to the second reaction zone to the feed rate of the composite particles to the second reaction zone is preferably from 0.02 to 0.3, or from 0.03 to 0.25, or from 0.04 to 0.2, or from 0.05 to 0.18, or from 0.06 to 0.15, based on grams of silicon in the silicon precursor gas per gram of the porous particle framework. In other words, during the residence time of the particles in the second reaction zone, from 0.02 to 0.3 grams of silicon atoms (in the form of the silicon precursor gas) are introduced into the reactor per gram of the porous particle framework.

Preferably, the second reaction zone is operated such that consumption of the silicon precursor gas is at least 50%, preferably at least 80%, preferably at least 90%, preferably at least 95%. Optionally, the second reaction zone is operated such that consumption of the silicon precursor gas is no more than 99%, or no more than 98%. A low level of unreacted silicon precursor gas in the effluent gas may be used as an indicator of controlled reaction rate.

In another implementation, the first reaction zone is operated such that consumption of the silicon precursor gas is no more than 90%, or no more than 80%, or no more than 60% or no more than 60%, and the effluent gas from the first reaction zone is used as at least part of the silicon precursor gas feed to the second reaction zone.

The composite particles withdrawn from the second reaction zone comprise the silicon deposited in the first reaction zone and preferably from 0.016 to 0.024 grams of silicon per gram of the porous particle framework deposited in the second reaction zone.

More preferably, from 0.2 to 1.6 grams of silicon per gram of the porous particle framework are deposited in the first reaction zone and from 0.016 to 0.024 grams of silicon per gram of the porous particle framework are deposited in the second reaction zone.

As discussed above, the ratio of the feed rate of the silicon precursor gas to the second reaction zone to the feed rate of the composite particles to the second reaction zone is based on fresh feed of the silicon precursor gas. Unreacted silicon precursor gas may be recovered from the effluent gas withdrawn from the second reaction zone in step (k) and recycled into the second reaction zone. Silicon precursor gas recycled to the second reaction zone in this way is not included in the feed ratio described above.

The effluent gas from the second reaction zone comprises by product gases from the CVI reaction and optionally unreacted silicon precursor gas. Preferably, the content of silicon precursor gas in the effluent gas from the second reaction zone is at least 1 vol %, or at least 2 vol %, or at least 5 vol %, or at least 10 vol %, or at least 15 vol %. Unreacted silicon precursor gas may be recovered and recycled as described above for the first reaction zone. Optionally, unreacted silicon precursor gases in the effluent gases from the first and second reaction zones may be recovered in a combined recovery process, for instance a semi-permeable membrane separation process, pressure-swing absorption process, or cryogenic separation process.

The second reaction zone is preferably operated in-line with the first reaction zone, such that composite particles withdrawn from the first reaction zone in step (e) pass continuously into the second reaction zone. Particles withdrawn from the first reaction zone in step (e) may be introduced into the second reaction zone in step (g) via an airlock valve, defined herein as a valve that is capable of separating a gas flow in the first reaction zone from the gas flow in the second reaction, zone, and in particular capable of separating a pressure differential between the two reaction zones. A preferred form of airlock valve for handling particles is a rotary valve (also known in the art as a rotary airlock feeder). Alternatively, the particles may be introduced into the second reaction zone in step (g) via a ball valve, a dome valve, a piston valve, or a screw feeder.

The process as defined in steps (g) to (k) is preferably operated under steady state conditions so as to ensure uniformity over time of the composite particles that are withdrawn from the first reaction zone in step (j).

The process of the invention optionally further comprises monitoring the partial pressure of the silicon precursor gas in the effluent gas withdrawn from the second reaction zone, and optionally adjusting one or more of the temperature in the second reaction zone, the pressure in the second reaction zone, or the feed rate of the silicon precursor gas to the second reaction zone in response to a measured deviation in the partial pressure of the silicon precursor gas from a steady state partial pressure.

### Feedstocks

The porous particles preferably have:
(i) a D₅₀ particle diameter in the range from 0.5 to 200 μm;
(ii) a total pore volume of micropores and mesopores as measured by gas adsorption in the range from 0.4 to 2.2 cm³/g; and
(iii) a PD₅₀ pore diameter as measured by gas adsorption of no more than 30 nm.

The term “particle diameter” as used herein refers to the equivalent spherical diameter (esd), i.e. the diameter of a sphere having the same volume as a given particle, wherein the particle volume is understood to include the volume of any intra-particle pores. The terms “D₅₀” and “D₅₀ particle diameter” as used herein refer to the volume-based median particle diameter, i.e. the diameter below which 50% by volume of the particle population is found. The terms “D₁₀” and “D₁₀ particle diameter” as used herein refer to the 10th percentile volume-based median particle diameter, i.e. the diameter below which 10% by volume of the particle population is found. The terms “D₉₀” and “D₉₀ particle diameter” as used herein refer to the 90th percentile volume-based median particle diameter, i.e. the diameter below which 90% by volume of the particle population is found.

Particle diameters and particle size distributions can be determined by standard laser diffraction techniques in accordance with ISO 13320:2009. Laser diffraction relies on the principle that a particle will scatter light at an angle that varies depending on the size the particle and a collection of particles will produce a pattern of scattered light defined by intensity and angle that can be correlated to a particle size distribution. A number of laser diffraction instruments are commercially available for the rapid and reliable determination of particle size distributions. Unless stated otherwise, particle size distribution measurements as specified or reported herein are as measured by the conventional Malvern Mastersizer™ 3000 particle size analyzer from Malvern Instruments™. The Malvern Mastersizer™ 3000 particle size analyzer operates by projecting a helium-neon gas laser beam through a transparent cell containing the particles of interest suspended in an aqueous solution. Light rays which strike the particles are scattered through angles which are inversely proportional to the particle size and a photodetector array measures the intensity of light at several predetermined angles and the measured intensities at different angles are processed by a computer using standard theoretical principles to determine the particle size distribution. Laser diffraction values as reported herein are obtained using a wet dispersion of the particles in 2-propanol with a 5 vol % addition of the surfactant SPAN™-40 (sorbitan monopalmitate). The particle refractive index is taken to be 2.68 for porous particles and 3.50 for composite particles and the dispersant index is taken to be 1.378. Particle size distributions are calculated using the Mie scattering model.

In general, the porous particles have a D₅₀ particle diameter in the range from 0.5 to 200 μm. Optionally, the D₅₀ particle diameter of the porous particles may be at least 1 μm, or at least 1.5 μm, or at least 2 μm, or at least 2.5 μm, or at least 3 μm, or at least 4 μm, or at least 5 μm. Optionally the D₅₀ particle diameter of the porous particles may be no more than 150 μm, or no more than 100 μm, or no more than 70 μm, or no more than 50 μm, or no more than 40 μm, or no more than 30 μm, or no more than 25 μm, or no more than 20 μm, or no more than 18 μm, or no more than 15 μm, or no more than 12 μm, or no more than 10 μm, or no more than 8 μm.

For instance, the porous particles may have a D₅₀ particle diameter in the range from 0.5 to 150 μm, or from 0.5 to 100 μm, or from 0.5 to 50 μm, or from 0.5 to 30 μm, or from 1 to 25 μm, or from 1 to 20 μm, or from 2 to 25 μm, or from 2 to 20 μm, or from 2 to 18 μm, or from 2 to 15 μm, or from 2 to 12 μm, or from 2.5 to 15 μm, or from 2.5 to 12 μm, or from 2 to 10 μm, or from 3 to 20 μm, or from 3 to 18 μm, or from 3 to 15 μm, or from 4 to 18 μm, or from 4 to 15 μm, or from 4 to 12 μm, or from 5 to 15 μm, or from 5 to 12 μm or from 5 to 10 μm, or from 5 to 8 μm. Particles within these size ranges and having porosity and a pore diameter distribution as set out herein are ideally suited for the preparation of composite particles for use in anodes for metal-ion batteries by a CVI process.

The D₁₀ particle diameter of the porous particles is preferably at least 0.2 μm, or at least 0.5 μm, or at least 0.8 μm, or at least 1 μm, or at least 1.5 μm, or at least 2 μm. By maintaining the D₁₀ particle diameter at 0.2 μm or more, the potential for undesirable agglomeration of sub-micron sized particles is reduced, and improved dispersibility of the composite particles formed.

The D₉₀ particle diameter of the porous particles is preferably no more than 300 μm, or no more than 250 μm, or no more than 200 μm, or no more than 150 μm, or no more than 100 μm, or no more than 80 μm, or no more than 60 μm, or no more than 40 μm, or no more than 30 μm, or no more than 25 μm, or no more than 20 μm.

The porous particles preferably have a narrow size distribution span. For instance, the particle size distribution span (defined as (D₉₀−D₁₀)/D₅₀) is preferably 5 or less, more preferably 4 or less, more preferably 3 or less, more preferably 2 or less, and most preferably 1.5 or less. By maintaining a narrow size distribution span, efficient packing of the particles in continuous reactors is more readily achievable.

The porous particles may have an average sphericity (as defined herein) of more than 0.5. Preferably they have an average sphericity of at least 0.55, or at least 0.6, or at least 0.65, or at least 0.7, or at least 0.75, or at least 0.8, or at least 0.85. Spherical particles are believed to aid uniformity of deposition and facilitate denser packing of particles, both in continuous reactors and of the final product when incorporated into electrodes.

It is possible to obtain highly accurate two-dimensional projections of micron scale particles by scanning electron microscopy (SEM) or by dynamic image analysis, in which a digital camera is used to record the shadow projected by a particle. The term “sphericity” as used herein shall be understood as the ratio of the area of the particle projection (obtained from such imaging techniques) to the area of a circle, wherein the particle projection and circle have identical circumference. Thus, for an individual particle, the sphericity S may be defined as:

$$S = \frac{4 \cdot π \cdot {A}_{m}}{{( {C}_{m} )}^{2}}$$

wherein Aₘ is the measured area of the particle projection and Cₘ is the measured circumference of the particle projection. The average sphericity Sₐᵥ of a population of particles as used herein is defined as:

$${S}_{av} = \frac{1}{n} {\sum }_{i = 1}^{n} [ \frac{4 \cdot π \cdot {A}_{m}}{{( {C}_{m} )}^{2}} ]$$

wherein n represents the number of particles in the population. The average sphericity for a population of particles is preferably calculated from the two-dimensional projections of at least 50 particles.

The porous particles comprise a three-dimensionally interconnected open pore network comprising micropores and/or mesopores and optionally a minor volume of macropores. In accordance with conventional IUPAC terminology, the term “micropore” is used herein to refer to pores of less than 2 nm in diameter, the term “mesopore” is used herein to refer to pores of 2-50 nm in diameter, and the term “macropore” is used to refer to pores of greater than 50 nm diameter.

References herein to the volume of micropores, mesopores and macropores in the porous particles, and also any references to the distribution of pore volume within the porous particles, relate to the internal pore volume of the porous particles used as the starting material in step (a) of the claimed process, i.e. prior to deposition of silicon into the pore volume in step (c).

The porous particles are characterised by a total volume of micropores and mesopores (i.e. the total pore volume in the range from 0 to 50 nm) in the range from 0.4 to 2.2 cm³/g. Typically, the porous particles include both micropores and mesopores. However, it is not excluded that porous particles may be used which include micropores and no mesopores, or mesopores and no micropores.

More preferably, the total volume of micropores and mesopores in the porous particles is at least 0.45 cm³/g, or at least 0.5 cm³/g, at least 0.55 cm³/g, or at least 0.6 cm³/g, or at least 0.65 cm³/g, or at least 0.7 cm³/g, or at least 0.75 cm³/g, or at least 0.8 cm³/g, at least 0.85 cm³/g, or at least 0.9 cm³/g, or at least 0.95 cm³/g, or at least 1 cm³/g. The use of high porosity conductive particles may be advantageous since it allows a larger amount of silicon to be accommodated within the pore structure.

The internal pore volume of the porous particles is suitably capped at a value at which increasing fragility of the porous particles outweighs the advantage of increased pore volume accommodating a larger amount of silicon. Preferably, the total volume of micropores and mesopores in the porous particles is no more than 2 cm³/g, or no more than 1.8 cm³/g, or no more than 1.6 cm³/g, or no more than 1.5 cm³/g, or no more than 1.45 cm³/g, or no more than 1.4 cm³/g, or no more than 1.35 cm³/g, or no more than 1.3 cm³/g, or no more than 1.25 cm³/g, or no more than 1.2 cm³/g, or no more than 1.1, or no more than 1, or no more than 0.95.

In some examples, the total volume of micropores and mesopores in the porous particles may be in the range from 0.45 to 2.2 cm³/g, or from 0.5 to 2 cm³/g, or from 0.55 to 2 cm³/g, or from 0.6 to 1.8 cm³/g, or from 0.65 to 1.8 cm³/g, or from 0.7 to 1.6 cm³/g, or from 0.75 to 1.6 cm³/g, or from 0.8 to 1.5 cm³/g.

In other examples, the total volume of micropores and mesopores in the porous particles may be in the range from 0.55 to 1.4 cm³/g, or from 0.6 to 1.4 cm³/g, or from 0.6 to 1.3 cm³/g, or from 0.65 to 1.3 cm³/g, or from 0.65 to 1.2 cm³/g, or from 0.7 to 1.2 cm³/g, or from 0.7 to 1.1 cm³/g, or from 0.7 to 1 cm³/g, or from 0.75 to 0.95 cm³/g.

In other examples, the total volume of micropores and mesopores in the porous particles may be in the range from 0.4 to 0.75 cm³/g, or from 0.4 to 0.7 cm³/g, or from 0.4 to 0.65 cm³/g, 0.45 to 0.75 cm³/g, or from 0.45 to 0.7 cm³/g, or from 0.45 to 0.65 cm³/g, or from 0.45 to 0.6 cm³/g.

In other examples, the total volume of micropores and mesopores in the porous particles may be in the range from 0.6 to 2 cm³/g, or from 0.6 to 1.8 cm³/g, or from 0.7 to 1.8 cm³/g, or from 0.7 to 1.6 cm³/g, or from 0.8 to 1.6 cm³/g, or from 0.8 to 1.5 cm³/g, or from 0.8 to 1.4 cm³/g, or from 0.9 to 1.5 cm³/g, or from 0.9 to 1.4 cm³/g, or from 1 to 1.4 cm³/g.

The PD₅₀ pore diameter of the porous particles is no more than 30 nm, and optionally no more than 25 nm, or no more than 20 nm, or no more than 15 nm, or no more than 12 nm, or no more than 10 nm, or no more than 8 nm, or no more than 6 nm, or no more than 5 nm, or no more than 4 nm, or no more than 3 nm, or no more than 2.5 nm, or no more than 2 nm, or no more than 1.5 nm. The term “PD₅₀ pore diameter” as used herein refers to the volume-based median pore diameter, based on the total volume of micropores and mesopores (i.e. the pore diameter below which 50% of the total micropore and mesopore volume is found). Therefore, in accordance with the invention, at least 50% of the total volume of micropores and mesopores is preferably in the form of pores having a diameter of less than 30 nm.

For the avoidance of doubt, any macropore volume (pore diameter greater than 50 nm) is not taken into account for the purpose of determining PD₅₀ values.

The volumetric ratio of micropores to mesopores in the porous particles may range in principle from 100:0 to 0:100. Preferably, the volumetric ratio of micropores to mesopores is from 90:10 to 55:45, or from 90:10 to 60:40, or from 85:15 to 65:35.

The pore size distribution of the porous particles may be monomodal, bimodal or multimodal. As used herein, the term “pore size distribution” relates to the distribution of pore size relative to the cumulative total internal pore volume of the porous particles. A bimodal or multimodal pore size distribution may be preferred since close proximity between micropores and pores of larger diameter provides the advantage of efficient ionic transport through the porous network to the silicon.

The total volume of micropores and mesopores and the pore size distribution of micropores and mesopores are determined using nitrogen gas adsorption at 77 K down to a relative pressure p/p₀ of 10⁻⁶ using quenched solid density functional theory (QSDFT) in accordance with standard methodology as set out in ISO 15901-2 and ISO 15901-3. Nitrogen gas adsorption is a technique that characterises the porosity and pore diameter distributions of a material by allowing a gas to condense in the pores of a solid. As pressure increases, the gas condenses first in the pores of smallest diameter and the pressure is increased until a saturation point is reached at which all of the pores are filled with liquid. The nitrogen gas pressure is then reduced incrementally, to allow the liquid to evaporate from the system. Analysis of the adsorption and desorption isotherms, and the hysteresis between them, allows the pore volume and pore size distribution to be determined. Suitable instruments for the measurement of pore volume and pore size distributions by nitrogen gas adsorption include the TriStar II and TriStar II Plus porosity analyzers, which are available from Micromeritics Instrument Corporation, USA, and the Autosorb IQ porosity analyzers, which are available from Quantachrome Instruments.

Nitrogen gas adsorption is effective for the measurement of pore volume and pore size distributions for pores having a diameter up to 50 nm, but is less reliable for pores of much larger diameter. For the purposes of the present invention, nitrogen adsorption is therefore used to determine pore volumes and pore size distributions only for pores having a diameter up to and including 50 nm (i.e. only for micropores and mesopores). PD₅₀ are likewise determined relative to the total volume of micropores and mesopores only.

In view of the limitations of available analytical techniques it is not possible to measure pore volumes and pore size distributions across the entire range of micropores, mesopores and macropores using a single technique. In the case that the porous particles comprise macropores, the volume of pores having diameter in the range from greater than 50 nm and up to 100 nm may be measured by mercury porosimetry and is preferably no more than 0.3 cm³/g, or no more than 0.20 cm³/g, or no more than 0.1 cm³/g, or no more than 0.05 cm³/g. A small fraction of macropores may be useful to facilitate electrolyte access into the pore network, but the advantages of the invention are obtained substantially by accommodating silicon in micropores and smaller mesopores.

Any pore volume measured by mercury porosimetry at pore sizes of 50 nm or below is disregarded (as set out above, nitrogen adsorption is used to characterize the mesopores and micropores). Pore volume measured by mercury porosimetry above 100 nm is assumed for the purposes of the invention to be inter-particle porosity and is also disregarded.

Mercury porosimetry is a technique that characterizes the porosity and pore diameter distributions of a material by applying varying levels of pressure to a sample of the material immersed in mercury. The pressure required to intrude mercury into the pores of the sample is inversely proportional to the size of the pores. Values obtained by mercury porosimetry as reported herein are obtained in accordance with ASTM UOP578-11, with the surface tension γ taken to be 480 mN/m and the contact angle φ taken to be 140° for mercury at room temperature. The density of mercury is taken to be 13.5462 g/cm³ at room temperature. A number of high precision mercury porosimetry instruments are commercially available, such as the AutoPore IV series of automated mercury porosimeters available from Micromeritics Instrument Corporation, USA. For a complete review of mercury porosimetry reference may be made to P. A. Webb and C. Orr in “Analytical Methods in Fine Particle Technology, 1997, Micromeritics Instrument Corporation, ISBN 0-9656783-0.

It will be appreciated that intrusion techniques such as gas adsorption and mercury porosimetry are effective only to determine the pore volume of pores that are accessible to nitrogen or to mercury from the exterior of the porous particles. Porosity values specified herein shall be understood as referring to the volume of open pores, i.e. pores that are accessible to a fluid from the exterior of the porous particles. Fully enclosed pores which cannot be identified by nitrogen adsorption or mercury porosimetry shall not be taken into account herein when determining porosity values. Likewise, any pore volume located in pores that are so small as to be below the limit of detection by nitrogen adsorption is not taken into account.

The porous particles are preferably porous conductive particles. A preferred type of porous conductive particles is porous carbon particles. The porous carbon particles preferably comprise at least 80 wt % carbon, more preferably at least 90 wt % carbon, more preferably at least 95 wt % carbon, and optionally at least 98 wt % or at least 99 wt % carbon. The carbon may be crystalline carbon or amorphous carbon, or a mixture of amorphous and crystalline carbon. The porous carbon particles may be either hard carbon particles or soft carbon particles.

As used herein, the term “hard carbon” refers to a disordered carbon matrix in which carbon atoms are found predominantly in the sp² hybridised state (trigonal bonds) in nanoscale polyaromatic domains. The polyaromatic domains are cross-linked with a chemical bond, e.g. a C—O—C bond. Due to the chemical cross-linking between the polyaromatic domains, hard carbons cannot be converted to graphite at high temperatures. Hard carbons have graphite-like character as evidenced by the large G-band (˜1600 cm⁻¹) in the Raman spectrum. However, the carbon is not fully graphitic as evidenced by the significant D-band (˜1350 cm⁻¹) in the Raman spectrum. The graphitic nature of carbon materials can be assessed by monitoring the ratio in peak intensity of the D-band to the G-band (ID/IG). The porous carbon particles may comprise an ID/IG of no more than 0.84, or no more than 0.75.

As used herein, the term “soft carbon” also refers to a disordered carbon matrix in which carbon atoms are found predominantly in the sp² hybridised state (trigonal bonds) in polyaromatic domains having dimensions in the range from 5 to 200 nm. In contrast to hard carbons, the polyaromatic domains in soft carbons are associated by intermolecular forces but are not cross-linked with a chemical bond. This means that they will graphitise at high temperature. The porous carbon particles preferably comprise at least 50% sp² hybridised carbon as measured by XPS. For example, the porous carbon particles may suitably comprise from 50% to 98% sp² hybridised carbon, from 55% to 95% sp² hybridised carbon, from 60% to 90% sp² hybridised carbon, or from 70% to 85% sp² hybridised carbon.

A variety of different materials may be used to prepare suitable porous carbon frameworks. Examples of organic materials that may be used include plant biomass including lignocellulosic materials (such as coconut shells, rice husks, wood etc.) and fossil carbon sources such as coal. Examples of resins and polymeric materials which form porous carbon particles on pyrolysis include phenolic resins, novolac resins, pitch, melamines, polyacrylates, polystyrenes, polyvinylalcohol (PVA), polyvinylpyrrolidone (PVP), and various copolymers comprising monomer units of acrylates, styrenes, α-olefins, vinyl pyrrolidone and other ethylenically unsaturated monomers. A variety of different carbon materials are available in the art depending on the starting material and the conditions of the pyrolysis process. Porous carbon particles of various different specifications are available from commercial suppliers.

The porous carbon particles may undergo a chemical or gaseous activation process to increase the volume of mesopores and micropores. A suitable activation process comprises contacting pyrolyzed carbon with one or more of oxygen, steam, CO, CO₂ and KOH at a temperature in the range from 600 to 1000° C.

Mesopores can also be obtained by known templating processes, using extractable pore formers such as MgO and other colloidal or polymer templates which can be removed by thermal or chemical means post pyrolysis or activation.

Alternatives to carbon-based conductive particles include porous metal oxides, such as oxides of titanium having the formula TiOₓ where x has a value greater than 1 and less than 2.

The porous particles preferably have a BET surface area of at least 750 m²/g, or at least 1,000 m²/g, or at least 1,250 m²/g, or at least 1,500 m²/g. The term “BET surface area” as used herein should be taken to refer to the surface area per unit mass calculated from a measurement of the physical adsorption of gas molecules on a solid surface, using the Brunauer-Emmett-Teller theory, in accordance with ISO 9277. Preferably, the BET surface area of the porous particles is no more than 4,000 m²/g, or no more than 3,500 m²/g, or no more than 3,250 m²/g, or no more than 3,000 m²/g or no more than 2,500 m²/g, or no more than 2,000 m²/g. For example, the porous particles may have a BET surface area in the range from 750 m²/g to 4,000 m²/g, or from 1,000 m²/g to 3,500 m²/g, or from 1,250 m²/g to 3,250 m²/g, or from 1,500 m²/g to 3,000 m²/g.

The porous particles preferably have a particle density of at least 0.35 and preferably less than 3 g/cm³, more preferably less than 2 g/cm³, more preferably less than 1.5 g/cm³, most preferably from 0.35 to 1.2 g/cm³. As used herein, the term “particle density” refers to “apparent particle density” as measured by mercury porosimetry (i.e. the mass of a particle divided by the particle volume wherein the particle volume is taken to be the sum of the volume of solid material and any closed or blind pores (a “blind pore” is pore that is too small to be measured by mercury porosimetry)). In general, the particulate additives used in the present invention have a low BET surface area and thus a relatively low volume of open pores. Accordingly, the apparent density as measured by mercury porosimetry is a close approximation to the “effective particle density” (the calculation of which includes the volume of open pores). Preferably, the porous particles have particle density of at least 0.4 g/cm³, or at least 0.45 g/cm³, or at least 0.5 g/cm³, or at least 0.55 g/cm³, or at least 0.6 g/cm³, or at least 0.65 g/cm³, or at least 0.7 g/cm³. Preferably, the porous particles have particle density of no more than 1.15 g/cm³, or no more than 1.1 g/cm³, or no more than 1.05 g/cm³, or no more than 1 g/cm³, or no more than 0.95 g/cm³, or no more than 0.9 g/cm³.

Preferred porous particles for use according to the invention include those in which:
(i) the D₅₀ particle diameter is in the range from 0.5 to 30 μm;
(ii) the total pore volume of micropores and mesopores as measured by gas adsorption is in the range from 0.5 to 1.5 cm³/g;
(iii) the PD₅₀ pore diameter as measured by gas adsorption is no more than 5 nm;

The silicon precursor gas is a silicon compound or mixture of silicon compounds that is gaseous at the temperature of the CVI process and thermally decomposable to form elemental silicon and by-product gases. Examples of suitable silicon precursor gases include silane (SiH₄), disilane (Si₂H₆), trisilane (Si₃H₈), methylsilane, dimethylsilane and chlorosilanes, and mixtures thereof. Preferably, the silicon precursor gas is selected from silane (SiH₄), disilane (Si₂H₆), trisilane (Si₃H₈), methylsilane and dimethylsilane. Silane (SiH₄) is the most preferred silicon-containing precursor gas.

Preferably, the silicon precursor gas is free of chlorine, for example containing less than 1 wt %, preferably less than 0.1 wt %, preferably less than 0.01 wt % of chlorine-containing compounds.

The silicon precursor gas may be used undiluted (neat) or in a dilution comprising at least 20 vol % of the silicon precursor gas and the balance of a gas selected from hydrogen and an inert gas, optionally wherein the inert gas is selected from nitrogen and argon. Preferably, the silicon precursor gas comprises at least 50 vol %, more preferably at least 60 vol %, more preferably at least 70 vol %, more preferably at least 80 vol %, more preferably at least 90 vol %, more preferably at least 95 vol %, more preferably at least 98 vol %, more preferably at least 99 vol % of the silicon precursor gas.

### Carbon Coating

The process of the invention optionally further comprises the steps of:
(l) providing a carbon deposition unit comprising at least one reaction zone
(m) introducing into the reaction zone a feedstock comprising composite particles withdrawn from the chemical vapour infiltration unit in step (e) or (j);
(n) introducing a carbon precursor gas into the reaction zone;
(o) providing conditions in the reaction zone that are effective to cause deposition of carbon within the pores and/or on the surface of the composite particles;
(p) withdrawing from the reaction zone composite particles comprising a porous particle framework, elemental silicon within the pores of the porous particle framework, and carbon within the pores and/or on the outer surfaces thereof.

The carbon deposited in step (o) is a pyrolytic carbon material that is formed by the thermal decomposition of a carbon containing gas (such as ethylene). It provides a number of performance advantages. It reduces the BET surface area of the composite particles by smoothing any surface defects and filling any remaining surface microporosity, thereby further reducing first cycle loss. It also improves the conductivity of the surface of the composite particles, reducing the need for conductive additives in the electrode composition. In addition, it creates an optimum surface for the formation of a stable SEI layer, resulting in improved capacity retention on cycling.

Steps (l) to (p) are preferably operated as a continuous process, such that the introduction of composite particles and carbon precursor gas into the reaction zone in steps (m) and (n) and the withdrawal of composite particles from the reaction zone in step (p) are each carried out continuously.

Preferably, the carbon deposition unit is operated in-line with the CVI unit, such that composite particles withdrawn from the CVI unit in step (e) or step (j) pass continuously into the carbon deposition unit in step (m).

The reaction zone of the carbon deposition unit preferably has the form of a tubular reactor having a first end, a second end and a length, wherein the particles are introduced via a particle inlet at the first end of the tubular reactor and wherein the composite particles comprising deposited carbon are withdrawn via a particle outlet at the second end of the tubular reactor.

The tubular reactor may be operated as a co-current reactor, wherein the carbon precursor gas is introduced via an inlet proximal to the first end of the tubular reactor and effluent gas is withdrawn via a gas discharge outlet proximal to the second end of the tubular reactor. Alternatively, the tubular reactor may be operated as a counter-current reactor, wherein the carbon precursor gas is introduced via an inlet proximal to the second end of the tubular reactor and effluent gas is withdrawn via a gas discharge outlet proximal to the first end of the tubular reactor.

Alternatively, the carbon precursor gas may be introduced into the tubular reactor via a plurality of inlets spaced apart along the length of the tubular reactor. In this case, the effluent gas may be withdrawn via one or more gas discharge outlets disposed at any position along the length of the tubular reactor. For example, the effluent gas may be withdrawn: (i) via a gas discharge outlet proximal to the second end of the tubular reactor; or (ii) via a gas discharge outlet proximal to the first end of the tubular reactor; or (iii) via a plurality of gas discharge outlets spaced apart along the length of the tubular reactor.

The tubular reactor of the carbon deposition zone preferably comprises an apparatus for conveying particles from the first end to the second end thereof, for example at least one auger, defined above.

Step (o) is suitably carried out at a temperature in the range from 350 to 700° C., or from 400 to 700° C. Preferably, the temperature in step (o) is no more than 680° C., or no more than 660° C., or no more than 640° C., or no more than 620° C., or no more than 600° C., or no more than 580° C., or no more than 560° C., or no more than 540° C., or no more than 520° C., or no more than 500° C.

The minimum temperature in step (o) will depend on the type of carbon precursor that is used. Preferably, the temperature in step (o) is at least 300° C., or at least 350° C., or at least 400° C.

Step (o) is suitably carried out at pressure in the range from 1 to 600 kPa, or from 10 to 500 kPa, or from 20 to 200 kPa, or from 50 to 150 kPa, or from 80 to 120 kPa, or about 100 kPa.

The mean residence time of particles in the reaction zone of the carbon deposition unit between introduction of composite particles into the reaction zone in step (m) and withdrawal of composite particles from the reaction zone in step (p) is preferably from 2 to 60 minutes, or from 5 to 30 minutes, or from 10 to 20 minutes.

The reaction zone of the carbon deposition unit preferably operates in plug-flow mode in respect of the particles, as described above.

The volume of the reaction zone in litres (L) is preferably in the range from (0.001 L·g⁻¹×F_{PP}×RT) to (0.02 L·g⁻¹×F_{PP}×RT), wherein F_{PP} is the feed rate of composite particles to the reaction zone based on grams of the porous particle framework per minute, and wherein RT is the mean residence time of particles in the first reaction zone in minutes. Preferably, the volume of the second reaction zone in litres (L) is less than (0.01 L·g⁻¹×F_{CP}×RT), more preferably less than (0.008 L·g⁻¹×F_{CP}×RT), more preferably less than (0.05 L·g⁻¹×F_{CP}×RT).

As described above, the mass of composite particles in the carbon deposition unit, and reaction parameters defined by reference to the mass of composite particles in the carbon deposition unit, are normalized to the mass of the porous particle framework. Accordingly, the mass of carbon added to the composite particles per gram of the porous particle feedstock can be directly compared to the mass of silicon added in each of the first and second reaction zones.

The ratio of the feed rate of the carbon precursor gas to the reaction zone to the feed rate of the composite particles to the reaction zone is preferably from 0.02 to 2 or from 0.03 to 1, or from 0.04 to 0.5, or from 0.04 to 0.2, or from 0.04 to 0.1, based on grams of carbon in the carbon containing gas per gram of the porous particle framework. In other words, during the residence time of the particles in the second reaction zone, from 0.02 to 2 grams of carbon atoms (in the form of the carbon precursor gas) are introduced into the reactor per gram of the porous particle framework. Preferably, the reaction zone of the carbon deposition unit is operated such that consumption of the carbon precursor gas is essentially 100%, such that the composite particles withdrawn from the reaction zone preferably comprise 0.02 to 0.06 grams, more preferably from 0.02 to 0.05 grams, more preferably from 0.03 to 0.04 grams of carbon derived from the carbon precursor gas per gram of the porous particle framework.

Suitable carbon precursor gases include:
(i) C₂-C₁₀ hydrocarbons, optionally wherein the hydrocarbons are selected from alkanes, alkenes, alkynes, cycloalkanes, cycloalkenes, and arenes, for example methane, ethylene, propylene, limonene, styrene, cyclohexane, cyclohexene, α-terpinene and acetylene;
(ii) bicyclic monoterpenoids, optionally wherein the bicyclic monoterpenoids are selected from camphor, borneol, eucalyptol, camphene, carene, sabinene, thujene and pinene; and
(iii) polycyclic hydrocarbons comprising from 10 to 25 carbon atoms and optionally from 1 to 3 heteroatoms, optionally wherein the polyaromatic hydrocarbon is selected from naphthalene, substituted naphthalenes such as di-hydroxynaphthalene, anthracene, tetracene, pentacene, fluorene, acenapthene, phenanthrene, fluoranthrene, pyrene, chrysene, perylene, coronene, fluorenone, anthraquinone, anthrone and alkyl-substituted derivatives thereof.

The carbon precursors used in step (o) may be used in pure form, or diluted mixture with an inert carrier gas, such as nitrogen or argon. For instance, the carbon precursor may be used in an amount in the range from 0.1 to 100 vol %, or 20 to 95 vol %, or 50 to 90 vol %, or 60 to 85 vol % based on the total volume of the precursor and the inert carrier gas.

### Passivation

The silicon deposited in the CVI reaction zone has hydride-terminated silicon surfaces that are highly reactive to oxygen. The process of the invention therefore preferably comprises a passivation step whereby the composite particles can undergo controlled oxidation with an oxygen containing gas to form a passivated material that is stable in air.

Therefore, the process of the invention preferably further comprises the steps of:
(q) providing a passivation unit comprising at least one reaction zone;
(r) introducing a feedstock comprising composite particles withdrawn from the chemical vapour infiltration unit in step (e) or (j) or from the carbon deposition unit in step (p) to the reaction zone;
(s) introducing an oxygen-containing gas into the reaction zone;
(t) withdrawing passivated composite particles from the reaction zone; and
(u) withdrawing an effluent gas from the reaction zone.

Steps (q) to (u) are preferably operated as a continuous process, such that the introduction of composite particles and oxygen-containing gas into the reaction zone in steps (r) and(s) and the withdrawal of composite particles and effluent gas from the reaction zone in steps (t) and (u) are each carried out continuously.

Step (s) is suitably carried out at a temperature in the range from 20 to 300° C., or from 20 to 200° C., or from 25 to 200° C., or from 25 to 180° C., or from 50° C. to 160° C. Preferably, the temperature in step(s) is no more than 150° C.

Step (s) is suitably carried out at pressure in the range from 1 to 600 kPa, or from 10 to 500 kPa, or from 20 to 200 kPa, or from 50 to 150 kPa, or from 80 to 120 kPa, or about 100 kPa.

Preferably, the passivation unit is operated in-line with the CVI unit or the optional carbon deposition unit, such that such that composite particles withdrawn from the CVI unit in step (e) or step (j), or alternatively composite particles withdrawn from the optional carbon deposition unit in step (p), pass continuously into the passivation unit in step (r).

The reaction zone of the passivation unit preferably has the form of a tubular reactor having a first end, a second end and a length, wherein the composite particles are introduced into the first end of the tubular reactor in step (r) and wherein the passivated composite particles are withdrawn from the second end of the tubular reactor in step (t).

The tubular reactor may be operated as a co-current reactor, wherein the oxygen-containing precursor gas is introduced via an inlet proximal to the first end of the tubular reactor and effluent gas is withdrawn via a gas discharge outlet proximal to the second end of the tubular reactor. Alternatively, the tubular reactor may be operated as a counter-current reactor, wherein the oxygen-containing gas is introduced via an inlet proximal to the second end of the tubular reactor and effluent gas is withdrawn via a gas discharge outlet proximal to the first end of the tubular reactor.

More preferably, the oxygen-containing gas may be introduced into the tubular reactor via a plurality of inlets spaced apart along the length of the tubular reactor. In this case, the effluent gas may be withdrawn via one or more gas discharge outlets disposed at any position along the length of the tubular reactor. For example, the effluent gas may be withdrawn: (i) via a gas discharge outlet proximal to the second end of the tubular reactor; or (ii) via a gas discharge outlet proximal to the first end of the tubular reactor; or (iii) via a plurality of gas discharge outlets spaced apart along the length of the tubular reactor.

Still more preferably, the plurality of inlets spaced apart along the length of the tubular reactor are assigned to two or more inlet groups spaced apart along the length of the reactor, wherein each inlet group comprises one or more inlets. For example, the plurality of inlets may be allocated to 2 to 10 inlet groups, wherein each inlet group independently comprises from 1 to 10 inlets. The oxygen concentration in the oxygen-containing gas increases in successive inlet groups, such that the oxygen-containing gas fed to the inlet group closest to the first end of the tubular reactor has a relatively low concentration of oxygen, and the oxygen-containing gas fed to the inlet group closest to the second end of the tubular reactor has a relatively high concentration of oxygen. For example, the concentration of oxygen in the oxygen-containing gas supplied to the inlet group closest to the first end of the tubular reactor is from 0.5 to 5 vol %, and the concentration of oxygen in the oxygen-containing gas supplied to the inlet group closest to the second end of the tubular reactor is from 15 to 21 vol % and optionally may be air.

By arranging the inlets into groups of increasing oxygen content, composite particles are steadily exposed to an increasing concentration of oxygen as they pass through the tubular reaction zone. When the composite particles first enter the passivation unit they are at their most reaction to oxygen. Accordingly, the oxygen-containing gas supplied to the inlet group closest to the first end of the tubular reactor comprises a relatively low oxygen content to constrain the rate of reaction. As the passivation reaction proceeds, and the composite particles become less reactive, the concentration of oxygen in the oxygen-containing gas may be increased to push the passivation reaction toward completion. As a result, the reaction of oxygen with the reactive silicon surfaces is controlled in such a way as to avoid large exotherms that might have a deleterious effect on the composite particle structure.

### Cooling

The process of the invention optionally further comprises a step of cooling the composite particles to ambient temperature. Cooling of the particles may be carried out by any convenient method. However, one suitable method includes passing the composite particles to a tubular cooling vessel which is provided with a cooling means. Particles are introduced via a particle inlet at the first end of the tubular cooling vessel and withdrawn via a particle outlet at the second end of the tubular cooling vessel.

The cooling means may comprise a cooling jacket supplied with a liquid coolant (e.g. water) or a coolant gas and/or a coolant gas (such as air) that is contacted with the composite particles in the cooling vessel.

The cooled particles may be collected, optionally classified to remove outsize particles and/or fines, and passed to a container for storage and subsequent delivery to downstream processes for manufacture of lithium ion batteries.

The present invention is further described with reference to the appended figures, in which:

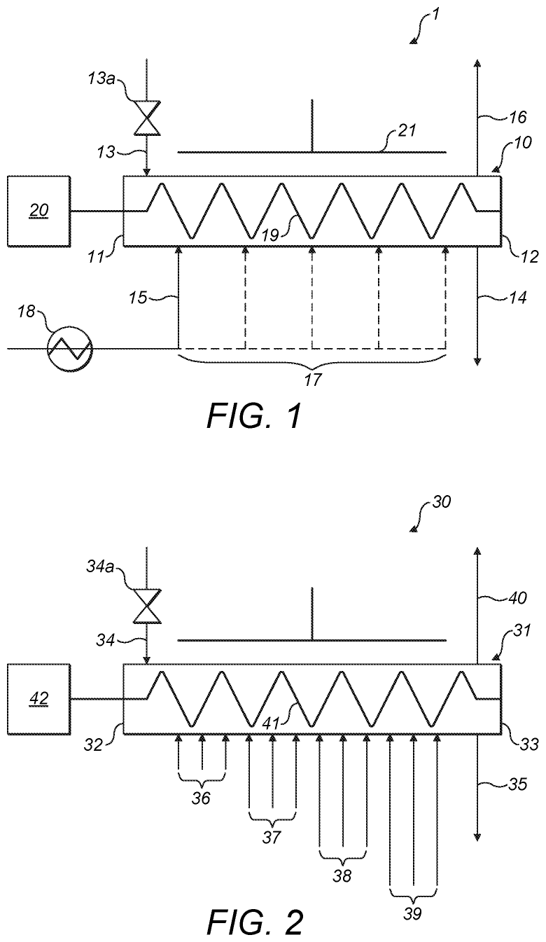

FIG. 1 is a schematic representation the apparatus of a chemical vapour infiltration (CVI) reaction zone operated according to an embodiment of the invention.

FIG. 2 is a schematic representation of the apparatus of a passivation reaction zone operated according to an embodiment of the invention.

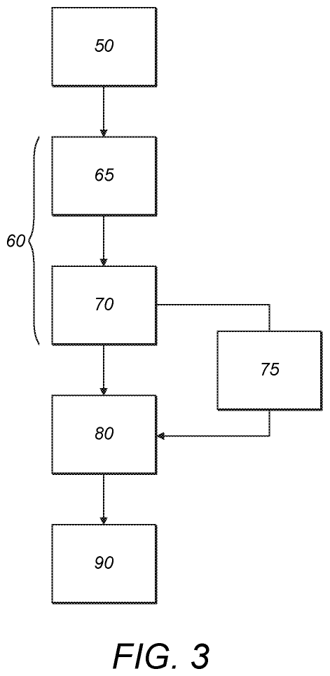

FIG. 3 depicts a flow chart of a process according to the invention.

With reference to FIG. 1, there is shown a CVI reaction zone (1) comprising a continuous tubular reactor (10) having a first end (11) and a second end (12) and a length. The tubular reactor (10) is oriented horizontally in the embodiment of FIG. 1. The tubular reactor comprises a particle inlet (13) at the first end, through which porous particles are introduced into the tubular reactor via an airlock valve (13a), and a particle outlet (14) at the second end, through which porous particles are withdrawn from the tubular reactor.

The tubular reactor comprises a gas inlet (15) at the first end of the tubular reactor for the introduction of the silicon precursor gas and a gas outlet (16) at the second end of the tubular reactor for the withdrawal of effluent gases. Optionally, the CVI reaction zone comprises a plurality of additional gas inlets (17) spaced apart along the length of the tubular reactor. The CVI reaction zone preferably comprises a gas heater (18) for pre-heating the silicon precursor gas.

The tubular reactor (10) further comprises an apparatus for conveying particles from the first end to the second end thereof in the form of an auger (19) powered by an electric motor (20). An electrical heater (21) is provided to control the internal temperature of the tubular reactor.

With reference to FIG. 2, there is shown a passivation unit (30) comprising a continuous tubular reactor (31) having a first end (32), a second end (33) and a length. The tubular reactor is oriented horizontally in the embodiment of FIG. 2. The tubular reactor comprises a particle inlet (34) at the first end, through which porous particles are introduced into the tubular reactor via an airlock valve (34a), and a particle outlet (35) at the second end, through which porous particles are withdrawn from the tubular reactor.

The tubular reactor comprises a plurality of gas inlets arranged along the length of the tubular reactor for the introduction of an oxygen-containing gas. The plurality of gas inlets are assigned to four inlet groups (36, 37, 38, 39) each comprising three gas inlets as shown. The oxygen concentration of the oxygen-containing gas is lowest in the gas supplied to the inlet group (36) closest to the first end (32) of the tubular reactor. In each successive inlet group (37, 38, 39) the oxygen concentration of the oxygen-containing gas is increased. The oxygen concentration in the oxygen-containing gas supplied to the inlet group (39) closest to the second end (33) of the tubular reactor is preferably approximately the same as the oxygen concentration in air. Optionally, the gas supplied to the inlet group (39) may be air. A gas outlet (40) is provided at the second end of the tubular reactor for the withdrawal of effluent gases.

The tubular reactor (31) further comprises an apparatus for conveying particles from the first end to the second end thereof in the form of an auger (41) powered by an electric motor (42). An electrical heater (43) is provided to control the internal temperature of the tubular reactor.

FIG. 3 shows a flow chart of an embodiment of the process of the invention. The process comprises a particle pre-treatment step (50), where the porous particle feedstock is pre-treated, preferably by pre-heating under an inert gas. The pre-treated particles are introduced into a CVI unit (60) comprising a first CVI reaction zone (65) for steps (a) to (f) and a second CVI reaction zone (70) for steps (g) to (k). Composite particles withdrawn from the second CVI reaction zone in step (k) may be passed directly to a passivation unit (80) for steps (q) to (u). Alternatively, the particles withdrawn from the reaction zone in step (k) may be passed to a carbon deposition unit (75) for steps (l) to (p) and the composite particles withdrawn from the carbon deposition unit in step (p) are then passed to the passivation unit (80) for steps (q) to (u). Finally, the passivated particles withdrawn from the passivation unit (80) in step (u) are passed to a cooling unit (90).

1. A continuous process for preparing composite particles, the process comprising the steps of:
(a) providing a chemical vapour infiltration unit comprising at least a first reaction zone;
(b) providing a feedstock comprising porous particles and continuously introducing the porous particles into the first reaction zone;
(c) continuously introducing a silicon precursor gas into the first reaction zone;
(d) providing conditions in the reaction zone that are effective to cause deposition of silicon in the pores of the porous particles;
(e) continuously withdrawing composite particles comprising a porous particle framework and elemental silicon within the pores of the porous particle framework from the first reaction zone; and
(f) continuously withdrawing an effluent gas from the first reaction zone.

2. The process according to claim 1 wherein the first reaction zone comprises a tubular reactor having a first end, a second end and a length, wherein the porous particles are introduced via a particle inlet at the first end of the tubular reactor and wherein the composite particles are withdrawn via a particle outlet at the second end of the tubular reactor.

3. The process according to claim 2, wherein the shape of the cross-section of the tubular reactor is selected from circular, elliptical, rectangular or square.

4. The process according to claim 3, wherein:
(i) the silicon precursor gas is introduced via an inlet proximal to the first end of the tubular reactor and wherein the effluent gas is withdrawn via a gas discharge outlet proximal to the second end of the tubular reactor; or
(ii) the silicon precursor gas is introduced via an inlet proximal to the second end of the tubular reactor and wherein the effluent gas is withdrawn via a gas discharge outlet proximal to the first end of the tubular reactor.

5. The process according to claim 3, wherein the silicon precursor gas is introduced via a plurality of inlets spaced apart along the length of the tubular reactor and wherein the effluent gas is withdrawn via
(i) a gas discharge outlet proximal to the second end of the tubular reactor; or
(ii) a gas discharge outlet proximal to the first end of the tubular reactor; or
(iii) a plurality of gas discharge outlets spaced apart along the length of the tubular reactor.

6. The process according to claim 5, wherein
the tubular reactor comprises means for conveying particles from the first end to the second end thereof.

7. The process according to claim 6, wherein said means for conveying particles from the first end to the second end of the tubular reactor comprises at least one auger, a moving belt type conveyor, a bucket type conveyor, a tube chain type conveyor, or a vertical conveyor, optionally wherein said means comprises twin augers.

8. The process according to claim 1, wherein the conditions in the first reaction zone include a reaction temperature in the range from 340 to 500° C., or from 350 to 480° C., or from 350 to 450° C., or from 350 to 420° C., or from 350 to less than 400° C., or from 355 to 395° C., or from 360 to 390° C., or from 365 to 385° C., or from 370 to 380° C.

9. The process according to claim 1, wherein the conditions in the first reaction zone include a pressure in the range from 1 to 10000 kPa, or from 10 to 6000 kPa, or from 20 to 4000 kPa, or from 50 to 2000 kPa, or from 80 to 1500 kPa, or from 90 to 1000 kPa, or from 90 to 600 kPa or about 100 kPa.

10. The process according to claim 9, wherein the conditions in the first reaction zone include a pressure in the range from 110 to 10000 kPa, or from 120 to 5000 kPa, or from 150 to 2000 kPa, or from 200 to 1800 kPa, or from 200 to 1600 kPa, or from 250 to 1500 kPa, or from 300 to 1200 kPa, or from 400 to 1000 kPa, or from 500 to 900 kPa, or from 600 to 800 kPa.

11. The process according to claim 1, wherein the mean residence time of particles in the first reaction zone between introduction of porous particles into the first reaction zone in step (b) and withdrawal of composite particles from the first reaction zone in step (e) is from 10 to 300 minutes, or from 15 to 240 minutes, or from 20 to 180 minutes, or from 30 to 120 minutes, or from 40 to 90 minutes.

12. The process according to claim 1, wherein the volume of the first reaction zone in litres is in the range from (0.003 L·g⁻¹×F_{PP}×RT) to (0.06 L·g⁻¹×F_{PP}×RT), wherein F_{PP} is the feed rate of porous particles to the first reaction zone in grams per minute, and wherein RT is the mean residence time of particles in the first reaction zone in minutes.

13. The process according to claim 1, wherein the ratio of the feed rate of the silicon precursor gas to the first reaction zone to the feed rate of the porous carbon particles to the first reaction zone is from 0.25 to 2, or from 0.4 to 1.9, or from 0.6 to 1.8, or from 0.7 to 1.7, or from 0.8 to 1.6, or from 0.9 to 1.6, or from 1 to 1.5, based on grams of silicon in the silicon precursor gas per gram of porous carbon particles.

14. The process according to claim 1, wherein step (b) further comprises pre-heating the feedstock comprising the porous particles in a pre-heating zone before introducing the pre-heated feedstock into the first reaction zone.

15. The process according to claim 14, wherein the feedstock comprising the porous particles is pre-heated to a temperature that is ≥(T_{RZ}−50)° C., wherein T_{RZ} is the reaction temperature of the first reaction zone.

16. The process according to claim 1, wherein the chemical vapour infiltration unit comprises at least first and second reaction zones, wherein the first reaction zone is the reaction zone as defined in any of the preceding claims and wherein the process further comprises:
(g) continuously introducing into the second reaction zone the composite particles withdrawn from the first reaction zone in step (e);
(h) continuously introducing a silicon precursor gas into the second reaction zone;
(i) providing conditions in the second reaction zone that are effective to cause deposition of silicon in the pores of the porous particles;
(j) continuously withdrawing composite particles comprising a porous particle framework and elemental silicon within the pores of the porous particle framework from the second reaction zone; and
(k) continuously withdrawing an effluent gas from the second reaction zone.

17. The process according to claim 16, wherein the second reaction zone comprises a tubular reactor having a first end, a second end and a length, wherein the composite particles withdrawn from the first reaction zone are introduced into the first end of the tubular reactor and wherein the composite particles are withdrawn from the second end of the tubular reaction zone.

18. The process according to claim 17, wherein:
(i) the silicon precursor gas is introduced via an inlet proximal to the first end of the tubular reactor and wherein the effluent gas is withdrawn via a gas discharge outlet proximal to the second end of the tubular reactor; or
(ii) the silicon precursor gas is introduced via an inlet proximal to the second end of the tubular reactor and wherein the effluent gas is withdrawn via a gas discharge outlet proximal to the first end of the tubular reactor.

19. The process according to claim 17, wherein the silicon precursor gas is introduced via a plurality of inlets spaced apart along the length of the tubular reactor and wherein the effluent gas is withdrawn via
(i) a gas discharge outlet proximal to the second end of the tubular reactor; or
(ii) a gas discharge outlet proximal to the first end of the tubular reactor; or
(iii) a plurality of gas discharge outlets spaced apart along the length of the tubular reactor.

20. The process according to claim 19, wherein the tubular reactor comprises at least one auger to convey particles from the first end to the second end thereof.

21. The process according to claim 20, wherein the conditions in the second reaction zone include a reaction temperature in the range from 350 to 450° C., or from 350 to 420° C., or from 350 to less than 400° C., or from 355 to 395° C., or from 360 to 390° C., or from 365 to 385° C. or from 370 to 380° C.

22. The process according to claim 21, wherein the conditions in the second reaction zone include a pressure in the range from 1 to 10000 kPa, or from 10 to 6000 kPa, or from 20 to 4000 kPa, or from 50 to 2000 kPa, or from 80 to 1500 kPa, or from 90 to 1000 kPa, or from 90 to 600 kPa or about 100 kPa.

23. The process according to claim 21, wherein the conditions in the first reaction zone include a pressure in the range from 110 to 10000 kPa, or from 120 to 5000 kPa, or from 150 to 2000 kPa, or from 200 to 1800 kPa, or from 200 to 1600 kPa, or from 250 to 1500 kPa, or from 300 to 1200 kPa, or from 400 to 1000 kPa, or from 500 to 900 kPa, or from 600 to 800 kPa.

24. The process according to claim 23, wherein the first and second reaction zones differ in respect of one or more of the reaction temperature, the reaction pressure, the particle residence time, and the feed rate of the silicon precursor gas.

25. The process according to claim 24, wherein the reaction temperature in the second reaction zone is from 5 to 50° C. lower, or from 10 to 20° C. lower than the reaction temperature in the first reaction zone.

26. The process according to claim 25, wherein the mean residence time of particles in the second reaction zone between introduction of composite particles into the second reaction zone in step (g) and withdrawal of composite particles from the second reaction zone in step (j) is from 2 to 60 minutes, or from 5 to 30 minutes, or from 10 to 20 minutes.

27. The process according to claim 26, wherein the volume of the second reaction zone in litres is in the range from (0.001 L·g⁻¹×F_{CP}×RT) to (0.02 L·g⁻¹×F_{CP}×RT), wherein F_{CP} is the feed rate of composite particles to the second reaction zone in grams per minute, and wherein RT is the residence time of particles in the second reaction zone in minutes.

28. The process according to claim 27, wherein the ratio of the feed rate of the silicon precursor gas to the second reaction zone to the feed rate of the composite carbon particles to the second reaction zone is from 0.02 to 0.3, or from 0.03 to 0.25, or from 0.04 to 0.2, or from 0.05 to 0.18, or from 0.06 to 0.15, based on grams of silicon atoms per gram of porous composite particles.

29. The process according to claim 28, wherein the composite particles withdrawn from the first reaction zone in step (e) are introduced into the second reaction zone in step (g) via an airlock valve, preferably a rotary airlock valve.

30. The process according to claim 1, wherein the porous particles have:
(i) a D₅₀ particle diameter in the range from 0.5 to 200 μm;
(ii) a total pore volume of micropores and mesopores as measured by gas adsorption in the range from 0.4 to 2.2 cm³/g; and
(iii) a PD₅₀ pore diameter as measured by gas adsorption of no more than 30 nm.

31. The process according to claim 30, wherein the porous particles have a D₅₀ particle diameter in the range from 0.5 to 150 μm, or from 0.5 to 100 μm, or from 0.5 to 50 μm, or from 0.5 to 30 μm, or from 1 to 25 μm, or from 1 to 20 μm, or from 2 to 25 μm, or from 2 to 20 μm, or from 2 to 18 μm, or from 3 to 20 μm, or from 3 to 18 μm, or from 3 to 15 μm, or from 4 to 18 μm, or from 4 to 15 μm, or from 4 to 12 μm, or from 5 to 15 μm, or from 5 to 12 μm or from 5 to 10 μm, or from 5 to 8 μm.

32. The process according to claim 31, wherein the porous conductive particles have a total volume of micropores and mesopores in the range from 0.45 to 2.2 cm³/g, or from 0.5 to 2 cm³/g, or from 0.55 to 2 cm³/g, or from 0.6 to 1.8 cm³/g, or from 0.65 to 1.8 cm³/g, or from 0.7 to 1.6 cm³/g, or from 0.75 to 1.6 cm³/g, or from 0.8 to 1.5 cm³/g.

33. The process according to claim 32, wherein the PD₅₀ pore diameter of the porous conductive particles is no more than 25 nm, or no more than 20 nm, or no more than 15 nm, or no more than 12 nm, or no more than 10 nm, or no more than 8 nm, or no more than 6 nm, or no more than 5 nm, or no more than 4 nm, or no more than 3 nm, or no more than 2.5 nm, or no more than 2 nm, or no more than 1.5 nm.

34. The process according to claim 1, wherein the wherein the silicon precursor gas is selected from silane (SiH₄), disilane (Si₂H₆), trisilane (Si₃H₈) methylsilane, dimethylsilane and chlorosilanes.

35. The process according to claim 1, further comprising:
(l) providing a carbon deposition unit comprising at least one reaction zone
(m) introducing into the reaction zone a feedstock comprising composite particles withdrawn from the chemical vapour infiltration unit in step (e) or (j);
(n) introducing a carbon precursor gas into the reaction zone;
(o) providing conditions in the reaction zone that are effective to cause deposition of carbon within the pores and/or on the surface of the composite particles;
(p) withdrawing from the reaction zone composite particles comprising a porous particle framework, elemental silicon within the pores of the porous particle framework, and carbon within the pores and/or on the outer surfaces thereof.

36. The process according to claim 1, further comprising:
(q) providing a passivation unit comprising at least one reaction zone;
(r) introducing a feedstock comprising composite particles withdrawn from the chemical vapour infiltration unit in step (e) or (j) or from the carbon deposition unit in step (p) to the reaction zone;
(s) introducing an oxygen-containing gas into the reaction zone;
(t) withdrawing passivated composite particles from the reaction zone; and
(u) continuously withdrawing an effluent gas from the reaction zone.

37. The process according to claim 36, wherein the at least one reaction zone comprises a tubular reactor having a first end, a second end and a length, wherein the composite particles are introduced into the first end of the tubular reactor in step (r) and wherein the passivated composite particles are withdrawn from the second end of the tubular reactor in step (t).

38. The process according to claim 37, wherein the oxygen-containing gas is introduced via a plurality of inlets spaced apart along the length of the tubular reactor and wherein the effluent gas is withdrawn via
(i) a gas discharge outlet proximal to the second end of the tubular reactor; or
(ii) a plurality of gas discharge outlets spaced apart along the length of the tubular reactor.

39. The process according to claim 38, wherein:
(i) the plurality of inlets is allocated to from 2 to 10 inlet groups;
(ii) each inlet group independently comprises from 1 to 10 inlets;
wherein the inlet groups are spaced apart along the length of the tubular reactor such that a proximal inlet group is proximate to the first end of the tubular reactor and a distal inlet group is proximate to the second end of the tubular reactor and wherein the concentration of oxygen in the oxygen containing gas increases from the proximal inlet group to the distal inlet group.

40. The process according to claim 39, wherein the concentration of oxygen in the oxygen containing gas supplied to the proximal inlet group is from 0.5 to 5 vol %.

41. The process according to claim 40, wherein the concentration of oxygen in the oxygen containing gas supplied to the distal inlet group is from 15 to 21 vol %, optionally wherein the oxygen-containing gas supplied to the distal inlet group is air.
